(19) United States
(12) Patent Application Publication
(10) Pub. No.: US 2019/0383071 A1
(43) Pub. Date: Dec. 19, 2019

(54) IMPLEMENTING LATCHING MECHANISM PRODUCING VARIABLE PRELOAD

(71) Applicant: International Business Machines Corporation, Armonk, NY (US)

(72) Inventors: Ryan Elsasser, Poughkeepsie, NY (US); Michael T. Peets, Staatsburg, NY (US); David C. Olson, Lagrangeville, NY (US); Khaalid P. McMillan, Wappingers Falls, NY (US)

(21) Appl. No.: 16/010,684

(22) Filed: Jun. 18, 2018

(51) Int. Cl. E05C 19/12; H05K 7/14

(52) U.S. Cl. CPC E05C 19/12; H05K 7/1401; H05K 7/1489

(57) ABSTRACT

A method and structures are provided for implementing a latching mechanism with a variable spring preload feature. The latching mechanism includes a latch housing and a latch slide. The latching mechanism includes a variable spring preload internal within the latch housing. The latch housing and latch slide have a standardized outer configuration to be incorporated in various products and configurations of hardware. The spring preload feature being varied to ensure latching mechanism remains latched during use.

### FIELD OF THE INVENTION

The present invention relates generally to the data processing field, and more particularly, relates to a method and structures for implementing a latching mechanism, such as used in information technology equipment (ITE), with a variable spring preload feature.

### DESCRIPTION OF THE RELATED ART

Various components require a latching mechanism for installation and removal, such as blade servers, manufactured by International Business Machines Corporation. Blade servers fit in a single chassis like books in a bookshelf and each is an independent server, with its own processors, memory, storage, network controllers, operating system and applications. The blade server simply slides into a bay in the chassis and plugs into a mid-plane or backplane, sharing power, fans, drives, switches, and ports with other blade servers.

Currently server hardware includes increasing numbers of I/O devices, for example, connecting a central planar board via connectors. Due to shock and vibration requirements, connector preload is required to ensure the connector remains plugged during dynamic shock and vibration loading. This requirement increases design complexity and cost due to increased tolerance requirements to ensure latching function and preload force.

A need exists for an efficient and effective mechanism for implementing variable preload within a latching mechanism. A need exists for an enhanced latching mechanism with a variable spring preload feature.

### SUMMARY OF THE INVENTION

Principal aspects of the present invention are to provide a method and structures for implementing a latching mechanism with a variable spring preload feature. Other important aspects of the present invention are to provide such method and structures substantially without negative effects and that overcome many of the disadvantages of prior art arrangements.

In brief, a method and structures are provided for implementing a latching mechanism with a variable spring preload feature. The latching mechanism includes a latch housing and a latch slide. The latching mechanism includes a variable spring preload feature internal within the latch housing. The latch housing and latch slide have a standardized outer configuration to be incorporated in various products and configurations of hardware. The spring preload feature is varied to ensure latching mechanism remains latched during use.

In accordance with features of the invention, the latching mechanism incorporates a single latch housing with the flexibility and ease of configuration for various loading requirements and product configurations, while providing a configurable preload.

In accordance with features of the invention, the latching flexibility of the latching mechanism can reduce tolerance requirements and associated cost.

In accordance with features of the invention, the latching mechanism achieves spring preload within a standardized outer latching mechanism, allowing the spring preload feature geometry and/or spring material to be quickly interchanged in response to physical testing, loading conditions, or product configurations and variations.

In accordance with features of the invention, the latching mechanism is uniquely flexible and configurable for use across various hardware configurations which may utilize identical external latching geometry.

In accordance with features of the invention, one of or both spring preload feature geometry and a spring material can be quickly interchanged in response to physical testing, loading conditions or product configurations and variations.

In accordance with features of the invention, the spring preload feature enables increased tolerance allowance for hardware dimension variations, flexibility for application to a wide range of preload requirements, and opportunities for common latching hardware across various manufacturers and products.

In accordance with features of the invention, the spring preload feature enables a user to easily vary the latch preload and damping characteristics while leaving the external latch geometry and interfacing surfaces unaltered.

### BRIEF DESCRIPTION OF THE DRAWINGS

The present invention together with the above and other objects and advantages may best be understood from the following detailed description of the preferred embodiments of the invention illustrated in the drawings, wherein:

FIG. 1 is an exploded perspective view not to scale illustrating of a latching structure including a latching mechanism in accordance with preferred embodiments;

FIGS. 2 and 3 respectively illustrating not to scale the latching structure of FIG. 1 including the latching mechanism assembled in an unlatched position and a latched position in accordance with preferred embodiments; and

FIGS. 4, 5, and 6 are detailed views schematically illustrating the latching mechanism of the latching structure of FIGS. 1, 2, and 3 in accordance with preferred embodiments.

### DETAILED DESCRIPTION OF THE PREFERRED EMBODIMENTS

In the following detailed description of embodiments of the invention, reference is made to the accompanying drawings, which illustrate example embodiments by which the invention may be practiced. It is to be understood that other embodiments may be utilized and structural changes may be made without departing from the scope of the invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

In accordance with features of the invention, a method and structures are provided for implementing a latching mechanism with a variable spring preload feature. The latching mechanism is uniquely flexible and configurable for use across various hardware configurations which may utilize identical external latching geometry.

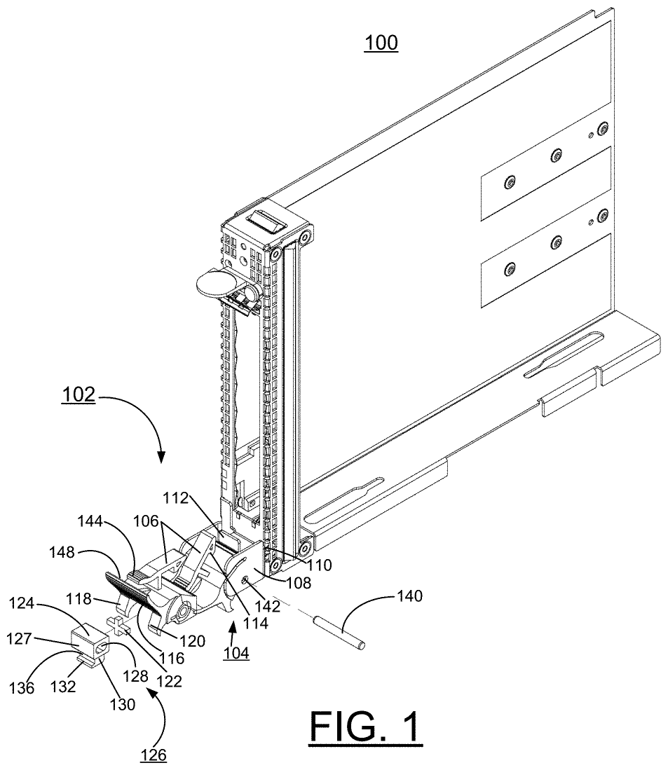

Having reference now to the drawings, in FIG. 1, there is shown a latching structure generally designated by the reference character 100 in accordance with the preferred embodiment. The latching structure 100 includes a latching mechanism generally designated by the reference character 102 in accordance with the preferred embodiment. The latching mechanism 102 is shown in an exploded view in FIG. 1.

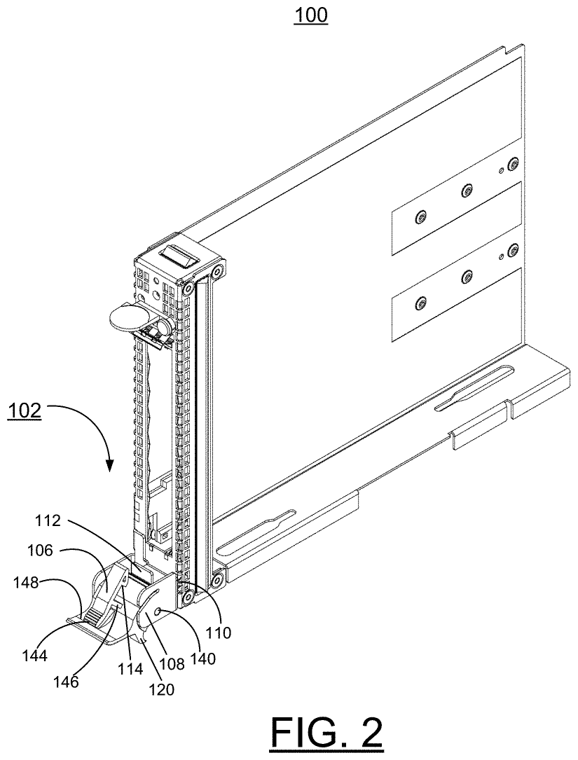

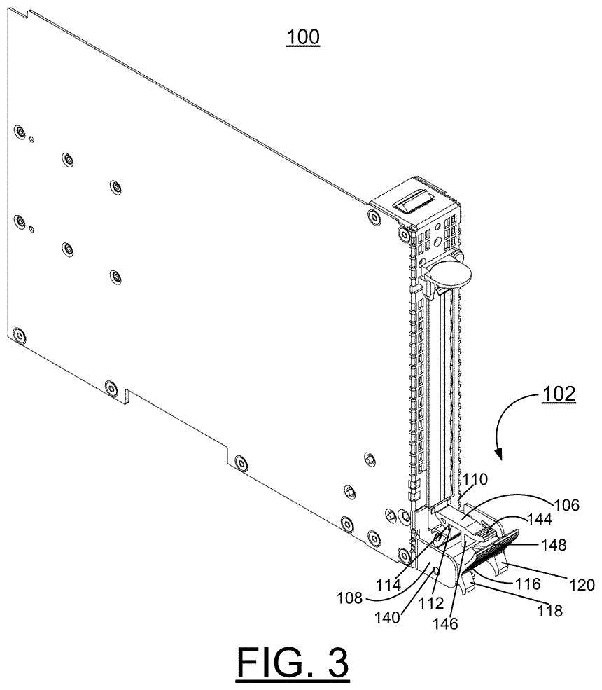

Referring also to FIGS. 2, and 3, the latching mechanism 102 is further illustrated in assembled form in an unlatched position in FIG. 2, and in a latched position in FIG. 3. The latching structure 100 including the latching mechanism 102 advantageously is used with various products, for example, a blade server unit, a power supply, a switch, a blower, I/O, and other components.

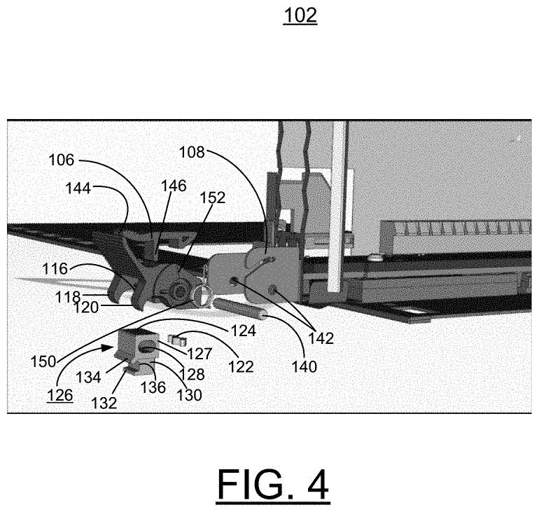

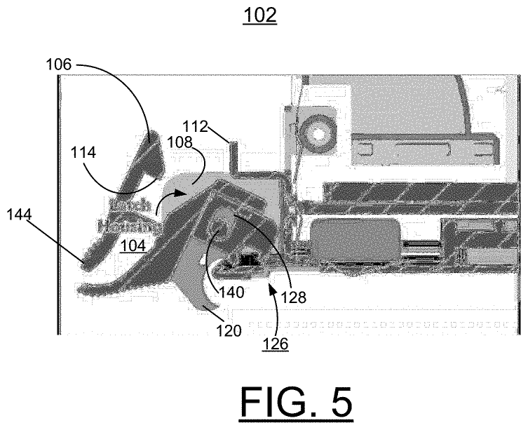

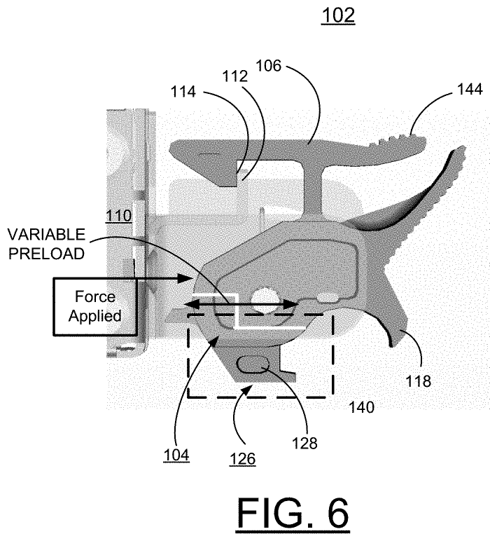

Referring also to FIGS. 4, 5, and 6, there are shown detailed views schematically illustrating the latching mechanism 102 in accordance with preferred embodiments. In FIG. 4, the latching mechanism 102 is shown in an exploded view. The latching mechanism 102 is illustrated in assembled form in an unlatched position in FIG. 5, and in a latched position in FIG. 6.

Referring now to FIGS. 1 and 4, the latching mechanism 102 includes a housing member generally designated by the reference character 104 carrying a latch slide 106, shown in two positions in FIG. 1. A housing interface member 108 is secured with an associated component 110 such as sheet metal drawer or cassette 110. The housing interface member 108 includes a generally centrally located mating flange 112 releasably engaging and retaining a mating end or proximal surface 114 of the latch slide 106, as shown in the latched position of latching mechanism 102 in FIGS. 3 and 6.

The latch housing member 104 includes a housing cavity 116 defined for entry between respective downwardly extending wall portions 118, 120 of the housing member 104. The latch housing member 104 receives in the housing cavity 116 a spring stop insert 122 and a housing spring insert 124 defining a latch spring preload feature 126.

Referring to FIG. 4, the housing spring insert 124 has a generally rectangular upper body 127 with an oval shaped opening 128 extending through the spring insert body 124. The housing spring insert 124 includes a lower portion 130 with an outwardly extending flange 132. The spring insert rectangular body 127 includes a lower, outwardly and downwardly extending flange 134 defining a channel 136 with the flange 132 in the lower spring insert portion 130.

Referring also to FIGS. 2 and 4, a pivot pin 140 is received through the latch spring preload feature 126 within the latch housing member 104 through an aligned opening 142 extending through opposing sides the housing interface member 108. The latching slide 106 includes a ribbed distal end 144 extending outwardly and a ledge 146 extending downwardly to limit positioning of the latching slide 106 in an unlatched position. As shown in FIG. 4, a tabbed ring 150 is received and retained within a housing recess 152.

In FIG. 2, the illustrated latching mechanism 102 is shown unlatched with an outwardly and upwardly extending ribbed ledge 148 of the housing 104 engaging the slide ribbed end 144 provided at the distal end of the latching slide 106.

In FIGS. 3 and 6, the illustrated latching mechanism 102 is shown in latching engagement with spring biasing provided in the closed or latched position of the latching mechanism 102. In the latched position, the ribbed distal end 144 of the latching slide 106 extends spaced apart from the ribbed ledge 148 of the housing 104.

In FIG. 5, the schematically illustrated latching mechanism 102 is shown unlatched to illustrate the operation of the preload feature 126. The slide 106 is shown with the slide mating surface 114 separated from the mating flange 112 of the housing interface member 108 of housing 104 that engages and retains the slide 106 in the latched position of latching mechanism 102, as shown in FIG. 6.

In FIG. 6, the schematically illustrated latching mechanism 102 is shown latched. In the latched or closed position of the latching mechanism 102, spring force is provided between rigid feature interfaces between the associated sheet metal drawer or cassette 110 and the latch spring preload feature 126. Force applied by the associated sheet metal drawer or cassette 110 is illustrated by the arrow and block labeled Force Applied. A variable preload applied by the latch spring preload feature 126 indicated in dashed line is indicated by an arrow labeled VARIABLE PRELOAD.

The housing spring stop 122 and housing spring insert 124 are formed, for example of a plastic material providing spring force action in the closed latched position of the latching mechanism 102. It should be understood that various other materials could be used to form the housing spring stop 122 and housing spring insert 124.

The housing 104 including the interface member 108 is formed, for example of a plastic material. It should be understood that various other materials could be used to form the housing 104, and the interface member 108.

It should be understood that the present invention is not limited to the illustrated latching mechanism 102; for example, various modification can be made without departing from the scope of the invention.

While the present invention has been described with reference to the details of the embodiments of the invention shown in the drawing, these details are not intended to limit the scope of the invention as claimed in the appended claims.

What is claimed is:

1. A structure for implementing a latching mechanism with a variable preload feature comprising:
a latch housing;
a latch slide;
a variable spring preload feature internal within the latch housing; and
said latch housing and latch slide having a standardized outer configuration, and said variable spring preload feature being varied to ensure latching mechanism remains latched during use.

2. The structure as recited in claim 1 wherein said latch housing and latch slide secure an associated component cassette.

3. The structure as recited in claim 1 wherein said spring preload feature is selectively varied to meet requirements of various hardware and loading conditions.

4. The structure as recited in claim 1 wherein said spring preload feature provides a preload to said latch slide only when said latching mechanism is forward latched position.

5. The structure as recited in claim 1 wherein load is applied to said latch slide via camming motion when said latching mechanism is closed.

6. The structure as recited in claim 1 wherein said variable spring preload feature provides variable latch preload and damping characteristics without changing external housing and latch slide geometry.

7. The structure as recited in claim 1 wherein said variable spring preload feature is incorporated within a single latch housing.

8. The structure as recited in claim 1 wherein said variable spring preload feature enables increased tolerance allowance for the latching mechanism.

9. The structure as recited in claim 1 wherein said variable spring preload feature of the latching mechanism is formed of a plastic material.

10. The structure as recited in claim 1 wherein said variable spring preload feature of the latching mechanism includes a housing spring insert and a spring stop insert.

11. A method for implementing a latching mechanism with a variable preload feature comprising:
providing a latch housing;
providing a latch slide;
providing a variable spring preload feature internal within the latch housing; and
providing said latch housing and latch slide with a standardized outer configuration, and said variable spring preload feature being varied based upon hardware and loading conditions.

12. The method as recited in claim 11 wherein providing said variable spring preload feature internal within the latch housing includes providing housing spring insert and a spring stop insert defining said variable spring preload feature.

13. The method as recited in claim 11 includes forming said housing spring insert and said spring stop insert of a plastic material.

14. The method as recited in claim 11 wherein providing said latch housing includes forming said latch housing of a plastic material.

15. The method as recited in claim 11 wherein providing said latch housing includes providing a housing interface member including a generally centrally located mating flange

16. The method as recited in claim 15 includes latching the latching mechanism with said generally centrally located mating flange releasably engaging and retaining a mating end surface of said latch slide

17. The method as recited in claim 11 includes providing variable latch preload and damping characteristics with said variable spring preload feature without changing external housing and latch slide geometry.

18. The method as recited in claim 11 includes applying load to said latch slide via camming motion when the latching mechanism is closed.

19. The method as recited in claim 11 includes securing an associated component cassette with said latch housing and latch slide.

20. The method as recited in claim 11 includes selectively varying said spring preload feature to meet requirements of various hardware and loading conditions.
